(19) United States
(12) Patent Application Publication
(10) Pub. No.: US 2012/0020040 A1
(43) Pub. Date: Jan. 26, 2012

(54) Package-to-package stacking by using interposer with traces, and or standoffs and solder balls

(76) Inventors: Paul T. Lin, Dallas, TX (US); Michael B. McShane, Austin, TX (US)

(21) Appl. No.: 13/136,185

(22) Filed: Jul. 26, 2011

Related U.S. Application Data
(60) Provisional application No. 61/400,309, filed on Jul. 26, 2010.

(51) Int. Cl. H05K 1/18

(52) U.S. Cl. 361/772

(57) ABSTRACT

The present invention discloses the structure and process for fabrication of an electronic package to contain and protect Package-to-Package (P2P) stacked module of integrated circuit (IC) chips. The process includes a step of providing an interposer that includes conductive traces interconnected between pre-designated contact pads disposed on a top and/or bottom surfaces for mounting at least a top or bottom packages of the IC chips with electric terminals contacting the contact pads disposed on the top and/or bottom surface of the interposer. Standoffs and passive components can also be added onto interposer in order to improve solder joints reliability, electrical performance and main board density at the same time. The inclusion of passive components on the interposer could enhance the electrical performance and the testability of the finished package stack.

This patent application is a Non-Provisional Application that claims a Priority Date of Jul. 26, 2010 based on a Provisional Application 61/400,309 filed by common Applicants of this application on Jul. 26, 2010.

### BACKGROUND OF THE INVENTION

1. Field of the Invention

This invention relates generally to the electronic package. More particularly, this invention relates to a package configuration and fabrication process for making improved electronic packages by using an interposer with standoffs and solder balls for package to package interconnecting and stacking.

2. Description of the Prior Art

Conventional technologies for packaging electronic devices by applying a configuration of direct package-to-package (P2P) stacking are still limited by a particular alignment requirement. Specifically, the direct package-to-package (P2P) stacking packages, implemented with either lead frame packages or solder ball BGAs, are required to have one-on-one alignment of their corresponding connections. Various one-on-one alignment configurations are described in U.S. Pat. Nos. 6,049,123; 6,168,970; 6,572,387; 5,455,740 for leadframe-to-leadframe P2P stacking packages, and U.S. Pat. Nos. 5,222,014; 7,667,338 for solder ball P2P stacking. Due to the one-on-one alignment requirement, the leads or solder ball array configurations arrangement for top and bottom packages have to be matched exactly.

Limited by the above-discussed one-on-one alignment requirement, the usefulness of the direct P2P stacking packages are restricted. As of now, electronic packages implemented with direct P2P stacking configurations are still limited only to packages of stacked memory products such as DRAMs, SDRAMs or Flash memories. In these P2P packages, identical leadframe packages are stacked along the perimeter outside the molded body. Meanwhile, for the BGA packages, the P2P direct stacking configurations are implemented with a limited layout where the solder balls can only be placed outside the molded body to use the solder balls for stacking interconnects. The solder ball locations have to be matched perfectly from the top and bottom parts. Because of these limitations, the top and bottom packages have to be customized. Therefore, the conventional direct P2P stacking packages limited by the one-to-one alignment requirement are essentially restricted to P2P stacking of same types of electronic packages while stacking of packages of different types would become impractical due to the alignment and routing requirement.

Another packaging technique implementing the configurations of stacking electronic devices is to produce a single package of multiple integrated circuit (IC) dice by using a die-to die (D2D) stacking approach. However, the wire bonding interconnects for a D2D package have to be placed along the perimeters or along the edges of the dice, i.e., on the space typically used to separate the dice, therefore, the D2D stack packaging techniques can not be used on dice with central pads configurations. Furthermore, D2D approach will suffer cumulative yield issue since each individual die can not be processed through burn-in and fully electrically tested before being assembled into single encapsulated body.

Application of the D2D packaging technologies is further limited by practical business concerns. The semiconductor companies generally are not willing to sell processed wafers or bare dice due to the reduced revenue compared to the revenue of selling packaged dice as assembled components. The profits generated from the backend processes by the semiconductor companies producing the IC dice are lost if processed wafers and bare dice are made available on the market. Also the process control and probed yield information will be clearly displayed in wafer selling.

Additionally, the sales and purchase of processed wafer or bare dice involve liabilities that are difficult to identify. Since bare die are not encapsulated and not protected by any encapsulant or packaging case, the bare dice are prone to damages. Whenever there are problems or reliability issues that occur within the multiple dice package, it is difficult to identify a responsible party to bear the costs of damages to the device or reliability problems because there are multiple parties involved in the manufacturing of the package devices that include semiconductor die suppliers and also the assembling companies. For these reasons, despite many potential benefits, the D2D packaging technologies are not practically useful to replace or even supplement the packages implementing the P2P stacking configurations.

Other than the difficulties and limitations of the P2P stacking packages, another major issue for implementing the P2P packages is the cost impact in assembling the present P2P packages, particularly when the P2P packages are assembled as customized packages. As described previously, present P2P will require customized parts to accommodate the other package for stacking. Customized parts will increase cycle time and the complexity of inventory control.

For these reasons, new and improved package configurations and method of assembling the P2P electronic packages are necessary to overcome these difficulties and limitations as now encountered in the industries by those of ordinary skill in the art.

### SUMMARY OF THE PRESENT INVENTION

It is therefore an aspect of the present invention to provide an improved packaging configuration and process to further improve the package-to-package (P2P) stacking assembling processes by using customized interposer to stack standard packages such that the above-discussed difficulties and limitations can be resolved.

One specific aspect of this invention includes a PCB or polymer film interposer formed with traces on the top and/or the bottom surface for stacking packages formed with via holes molded onto leadframe or BGA substrate package such that the P2P stacking solder joints can be placed directly over the die area of the bottom packages so that the P2P stacking can be built with the smallest footprint possible.

Another aspect of this invention includes a PCB interposer with top conductive traces connected to standard surface mounted (SMT) packages and bottom traces connected to via holes BGA package with via holes such that the P2P stacking packages can be more flexible and conveniently implemented.

Another aspect of this invention includes an—interposer with attached standoffs and solder balls to stack standard packaged device such as a standard QFP or TSOP on a molded via BGA package such that the P2P stacking packages can be more flexible and conveniently implemented.

Another aspect of this invention includes a PCB interposer with standoffs, solder balls and passive components for stacking standard SMT on molded via BGA package such that the P2P stacking packages can be more flexible and conveniently implemented.

Another aspect of this invention includes a PCB interposer to assemble stacked packages with optional polymer bump configurations to package specialized packages such as flip chip interconnections so that lower temperature stacking processing can be used on P2P packages and polymer bumps can compensate package warpage and absorb thermal stress.

Briefly, in a preferred embodiment, the present invention comprises an electronic package for containing and protecting stacked packages of integrated circuit chip therein. The electronic package includes an interposer with conductive traces interconnected between pre-designated contact pads disposed on a top and bottom surface for mounting at least a top and bottom packages of the IC chips with electric terminals contacting the contact pads disposed on the top and bottom surface of the interposer. In a preferred embodiment, the interposer further includes standoffs disposed on either a top surface or a bottom surface of the interposer. In another embodiment, the interposer further includes solder balls or conductive polymer bumps disposed on either a top surface or a bottom surface of the interposer. In another embodiment, the interposer further includes passive electrical components disposed on either a top surface or a bottom surface of the interposer.

These and other objectives and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a cross sectional view depicting a PCB interposer with contact pads on both top and bottom surfaces.

FIG. 1B is a cross sectional view of a package to be implemented with the PCB interposer of FIG. 1A with filled solder vias on the top and bottom half of molded body for stacking and connecting with via holes molded in leadframe BGA package.

FIG. 2 is a cross sectional view showing a package implemented with a PCB interposer with top conductive traces connect to standard surface mounted gull wing leadframe packages.

FIG. 3 is a cross sectional view showing a package implemented with a PCB interposer with standoffs and solder balls to stack standard QFP on a molded via BGA package.

FIG. 4 is a cross sectional view showing a package implemented with a PCB interposer with standoffs, solder balls and passive components for stacking standard SMT (package) on molded via BGA package.

FIG. 5 is a cross sectional view showing a package implemented with a PCB interposer using polymer bumps to assemble stacked packages

FIG. 6 is a cross sectional view of an interposer with attached PCB standoffs and solderable polymer balls on the bottom side to be stacked onto flip chip package with under-fills between the flip chip surface and the BGA substrate.

FIG. 7 is the bottom portion of FIG. 6 to indicate that laminated PCB interposer with mechanical standoffs which is the basic building block of P2P structure, the top surface of interposer can be built with different kinds of SMT footprints to accommodate various SMT packages.

FIG. 8 is a cross section view of P2P structure stacked with various package types and different pitches on top of the interposer.

FIG. 9 is a cross section view of P2P with stacking solder joints directly above the flip chip die area of the bottom package to create the smallest possible footprint to show a unique feature achievable by using the interposer of this invention.

### DETAILED DESCRIPTION OF THE PREFERRED EMBODIMENT

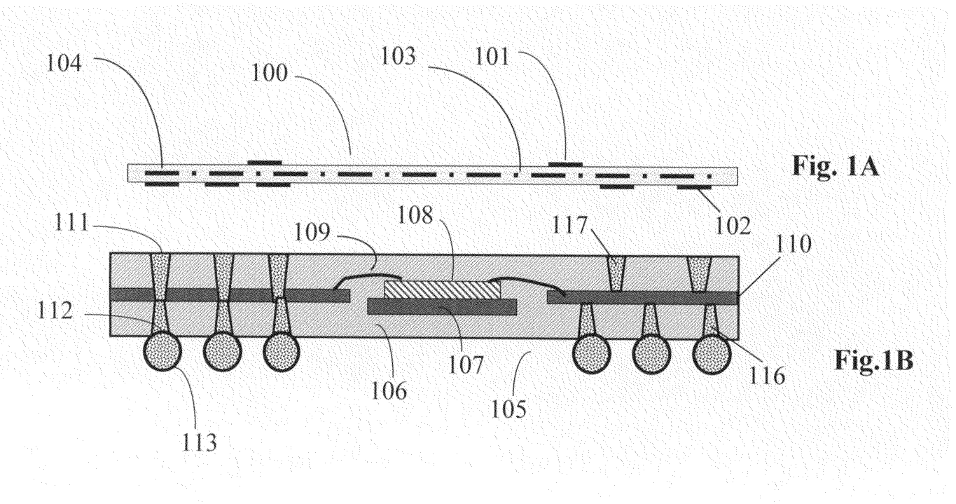

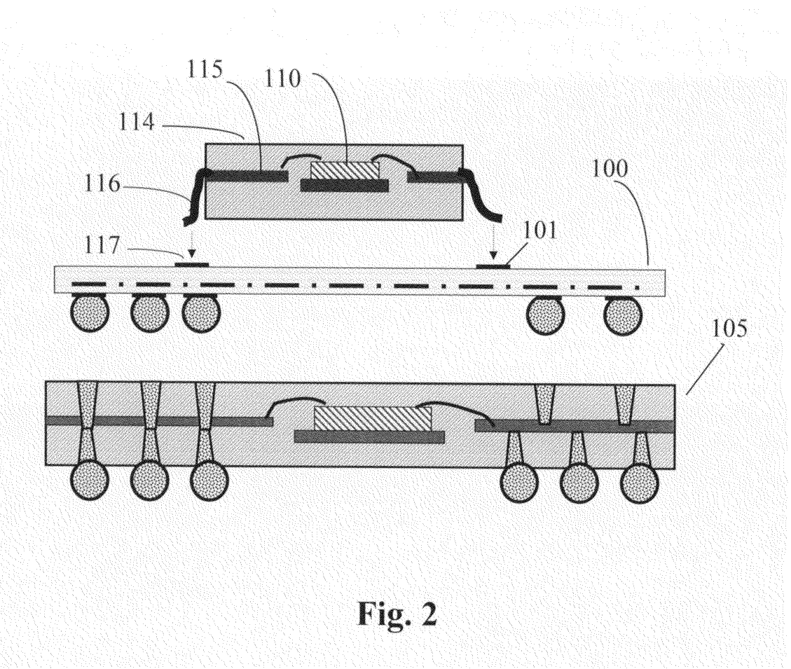

FIG. 1A is a cross sectional view of a customized printed circuit board (PCB) interposer 100 that is designed to provide interconnecting electrical routing from a top package 114 (FIG. 2) and mounted on top of the interposer, to a bottom package 105 as that shown in FIG. 1B. Additional packaging features and options are further described below. The interposer 100 shown in FIG. 1A has a top surface that includes a top contact pad 101 and the interposer 100 further has a bottom surface that includes bottom contact pads 102. The bottom contact pads 102 are arranged with a layout that matches with the via-holes contact 111 and 117 located on the top side of the bottom package 105 shown in FIG. 1B. The interposer 100 is formed with laminated core layers, 103 that include connecting trace 104 disposed in the intermediate layers of the PCB and connect to the bottom contact pad 102.

The bottom package 105 shown in FIG. 1B comprises a leadframe package that included a molded lead frame 110, encapsulated in encapsulant 106 or includes a substrate BGA package, as described in U.S. Pat. No. 7,667,338. The disclosures made in U.S. Pat. No. 7,667,338 are hereby incorporated by reference in this application. The bottom package 105 contains an integrated circuit (IC) chip 108 connected by the bonding wires 109 to the electrical terminals disposed on the leadframe 110. The bottom package 105 further includes a plurality of via connectors, e.g., via connectors 111, 112, 116 and 117, with the via connectors opened through the encapsulant 106 to electrically connected to the solder balls 113 on the bottom and to the contact pads 102 disposed on the bottom surface of the PCB interposer 100 of FIG. 1A.

FIG. 2 shows the interposer 100 of FIG. 1A provides convenient interconnections between a second standard lead-frame packages 114 from the top of the interposer to the first package 105 disposed below the interposer 100 with attached solder balls. The second/top package 114 includes another IC chip 110 are wire bonded to lead frame 115 that is connected electrically to gull wing lead 116. Then, the second package 114 will be surface mounted to the contact pads 117 and 101 on the top surface of the interposer. The traces formed inside the interposer, and the via-connectors penetrates through laminated layers of the interposer are implemented to connect the top and bottom solder pads. For specific applications, the interposer contact pads disposed on the top and bottom surfaces of the interposer 100 are configured with footprints for comply with top and bottom packages with standard package footprints to be stacked for P2P structure. These standard footprints of packages could be of standards as TSOPs (Thin Small Outline Packages), QFPs (Quad Flat Packages in Ref.1)), CSP (Chip Size Packages), BGAs (Ball Grid Array) or another Via Holes BGA with different pad configurations as described in “Microelectronics Packaging Handbook” edited by Tummala and Rymaszewski of IBM published by Van Nostrand, N.Y. Library of Congress Catalog No. 88-14254.

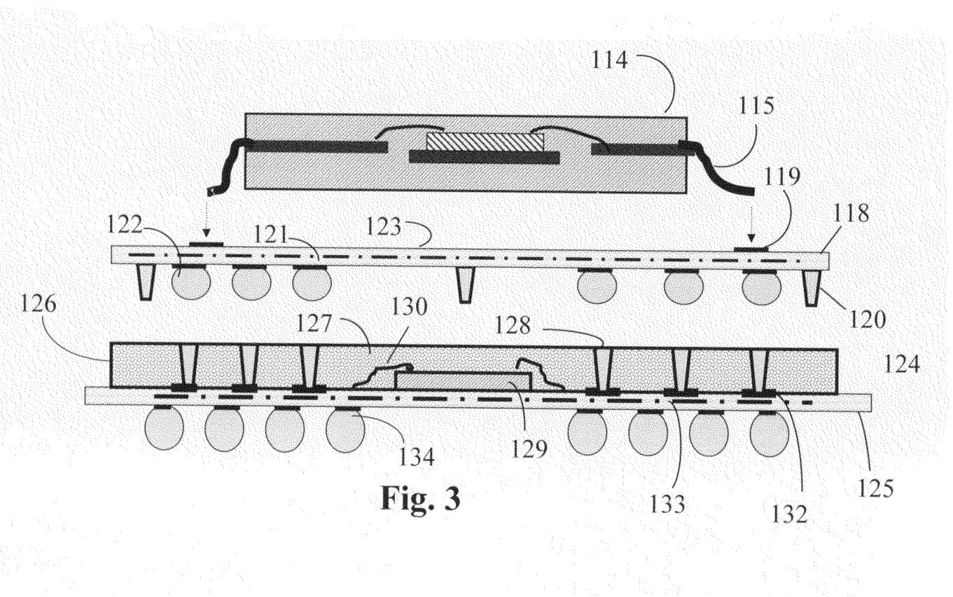

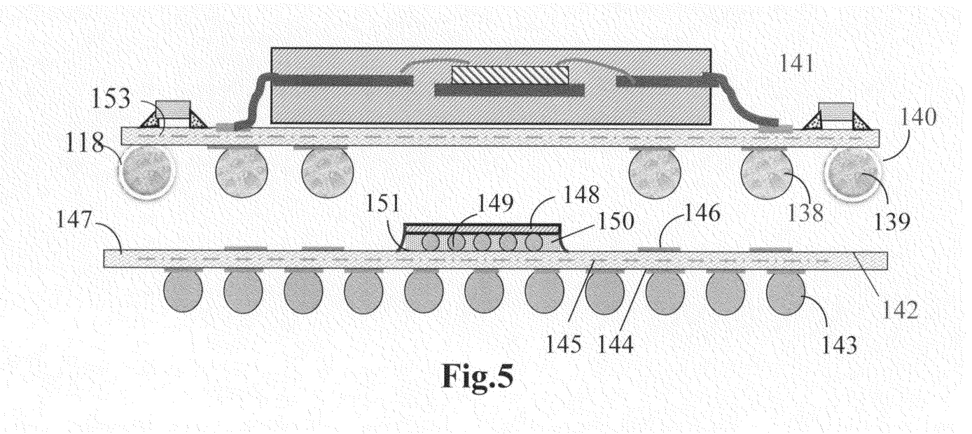

FIG. 3 shows an interposer 118 that includes standoffs 120 adhesively attached on the bottom surface of the interposer 118. The interposer 118 further includes solder balls 122 attached onto the bottom surface [symbol] Note that standoffs cab be off different shape to be place in many locations in order to ease stacking processing and provide a positive spacing between interposer and the stacked package Standoffs can be made of various material and be adhesively attached onto the interposer as shown in FIG. 3. One can also use solder coated polymer ball and soldered onto interposer as shown as element 139 in FIG. 5. The interposer 118 as shown provides more flexibility in the development of the stacking processes. Once the size, shape and locations for standoffs 120 have been optimized, hard tooling can be made into steel mold to build standoffs using mold compound; thus eliminates the step of building standoffs. FIG. 3 shows a standard leadframe QFP package 114 mounted on top of the interposer 118. A BGA substrate 125 is mounted with an IC chip 129 covered under a mold cap 126 composed of an encapsulant material 127 has via holes 128 opened through the mold cap 126 disposed on the bottom side of the interposer. Molded BGA 124 is configured to stack underneath the interposer 118 as the bottom package for the stacked P2P assembly. In order to accommodate potential warps that may be developed in the operation of the bottom package, the standoff 120 as that shown in FIG. 3 may also be implemented with a polymer elastomer material, or spring loaded pin. The polymer bumping material and process as will be further described in FIG. 5 below can provide additional benefits to form compliant interconnections with standoffs that are more reliable and can be manufactured at a lower cost. Since the interposer uses a much looser pitch than that of the flip chips, the cost and technologies of screening polymer bumps onto the interposer of this invention can be accomplished at a reduced cost as compare to placing solder balls and standoffs in two different processing steps.

As shown in FIG. 3, the bottom surface of the interposer 118 is also deposited with solder pads 121 to attach the solder balls 122 to the interposer 118. The solder balls 122 are then surface mounted and vertically stacking onto the via-holes 128 filled with via conductors for electrically connecting to the molded BGA package 124 stacked underneath the interposer 118. The standoffs 120 that are placed at the corners or center, can also serve as positive spacing structural support to prevent the collapse of solder interconnections.

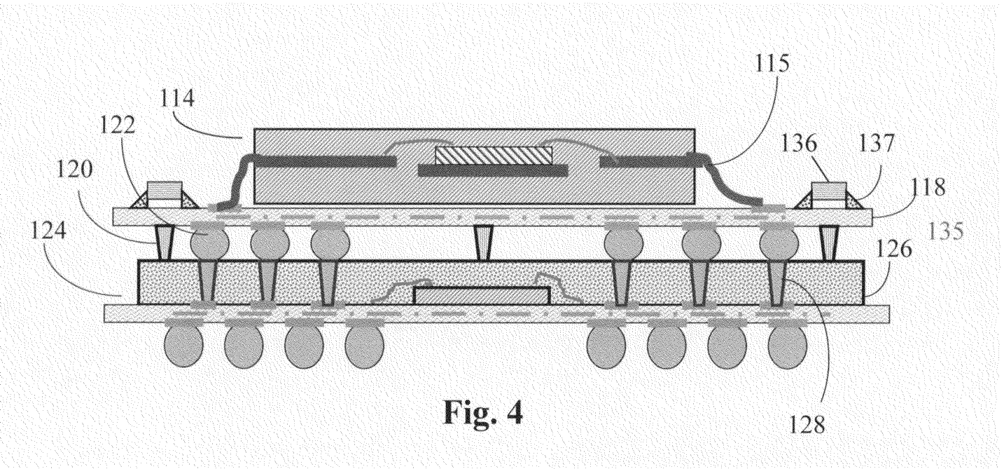

FIG. 4 shows the interposer 118 that includes standoffs 120, solder balls 122 on the bottom surface and passive components 136 attached to the top surface of the interposer by solder paste 137 and stacking standard surface mounted (SMT) package 114 from the top. The solder balls 122 disposed on the bottom surface of the interposer 118 further provide a configuration to surface mount onto the bottom package 124 formed with via hole connectors 128 with footprint matched to the solder balls 122 disposed on the bottom surface of the interposer 118. The passive components 136 may include resistors or capacitors formed and mounted on interposer 118 to increase board density and device performance characteristics as part of the P2P stacked package. By placing passive components on interposer, one can test the functionality at POP module level instead of testing at the mother board level to improve flexibilities and manufacturability.

FIG. 5 shows a BGA substrate 147 mounted with a flip chip 148 jointing through fine pitch solder bumps 149. Under-fill material 150 was used to fill the spaces between the flip chip surface and the fine pitch solder bumps 149 without using the over-molded encapsulant. Since the backside of flip chip IC is actually exposed. In this case, the solder balls 138 and polymer coated solder ball 139 disposed on the bottom surface of the interposer 118 are directly connected to the exposed pads 146 on the BGA substrate 147. Proper spacing is maintained by the polymer standoff ball 139. Solder balls 143 attached to the bottom surface of the BGA substrate will be used to mount the stacked module to the mother board.

Polymer bumping technique is applied here to form standoffs or the interconnection bumps on PCB interposer. Silver filled polymer bumps can be made of either thermoset or thermoplastic polymer such as EPO-TEK E2101 (thermoset) and EPO-TEK E5022 (thermoplastics) formulated for stencil printing process. These polymer bumps can be joined with relative low temperature and with good thermal conductivity and low elastic modulus to ease manufacturability and improve the reliability of interposer stacking structure.

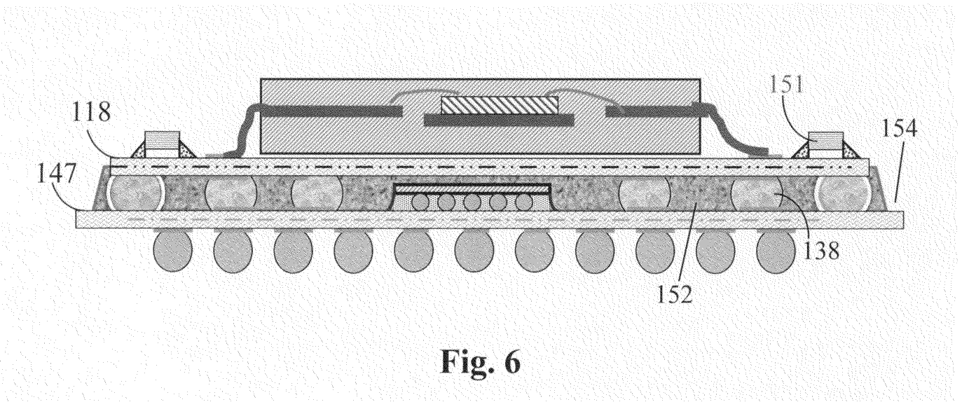

FIG. 6 shows an alternate embodiment, the P2P stack package by stacking the top package with the interposer 118 onto the bottom package 142 of FIG. 5 by filling thermal conductive gel or grease 152 between the interposer 118 and the bottom package 142. The under-fill 152 composed of good thermal conductive but not electrical conductive material such as silicon gel loaded with silicon nitride or other ceramic oxide particles which will improve the thermal dissipation and keep the contaminants out of the P2P structure thus improves the reliability, and life cycles of the devices.

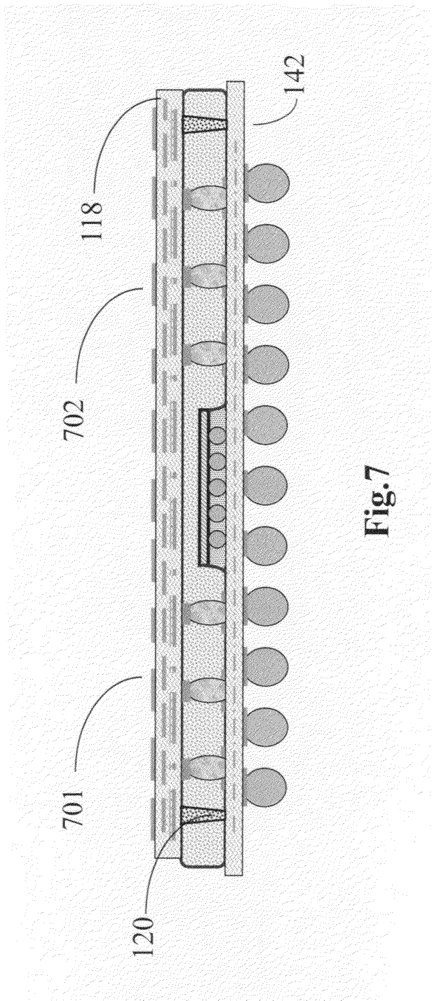

FIG. 7 is a cross sectional view for showing the lower portion of FIG. 6 except that the interposer 118 is mounted onto the bottom package 142 with standoffs. The interposer 118 is composed of a compound with high thermal conductivity to improve the power dissipation of the stacked structure. A plurality of conductive traces 701 and contact pads 702 are formed on the top surface of the interposer 118. These conductive traces and contact pads are designed and formed with specific footprints to accommodate pre-designated surface mountable packages or devices to readily mount on top of the interposer such that the bottom package 142 may be conveniently integrated with various products mounted onto the interposer 118.

FIG. 7 shows the lower portion of FIG. 6 only which is the interposer being mounted onto the bottom package with standoffs and thermal compound to improve the power dissipation of the stacked structure. Note the top side traces 701 and contact pads 702 can be designed to 5 accommodate any desired SMT footprints in order to integrate various products. Some examples of the applications are:
1) Standard microprocessor unit (MCU) on top of customized Graphic Processor Unit (GPU).
2) Integrates Standard digital products on top of customized analog products.
3) Mounting different kinds of memory products, such as DRAM, SRAM, ROM or flush memories onto Processor package.
4) Integrates different kinds of memories where different wafer processing will be required such as DRAM with Static RAM or flush memory.
5) Stacking Sensor or MEM devices onto processor.

In view of the broad range of applications, one can choose to provide and sell the base module only or to continue on with the top packages 20 mounting and build the complete P2P structure which will be described in Process Flow section.

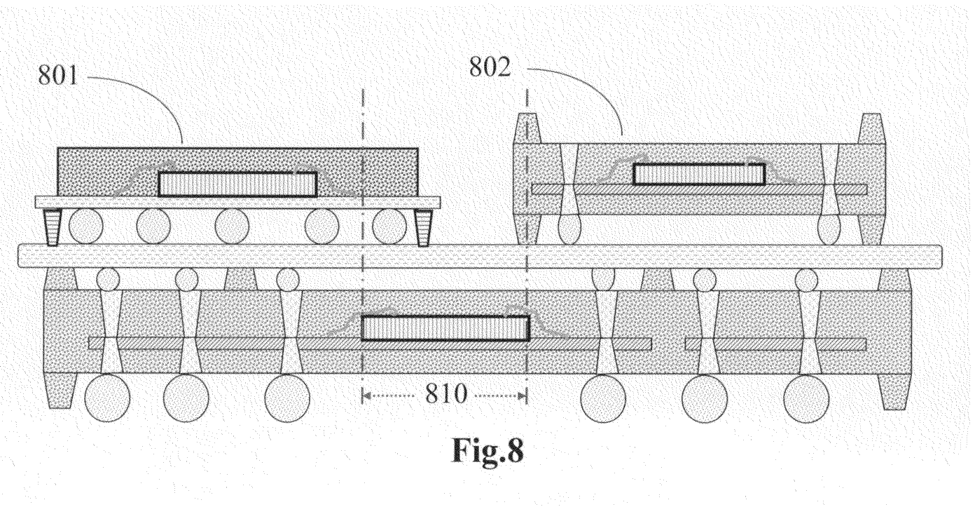

FIG. 8 shows the bottom package base module mounted with various types of SMTs 801 and 802, on top of interposer using different land pitches. Notice that some of the stacking solder joints can be placed directly over 25 the bottom die area 810.

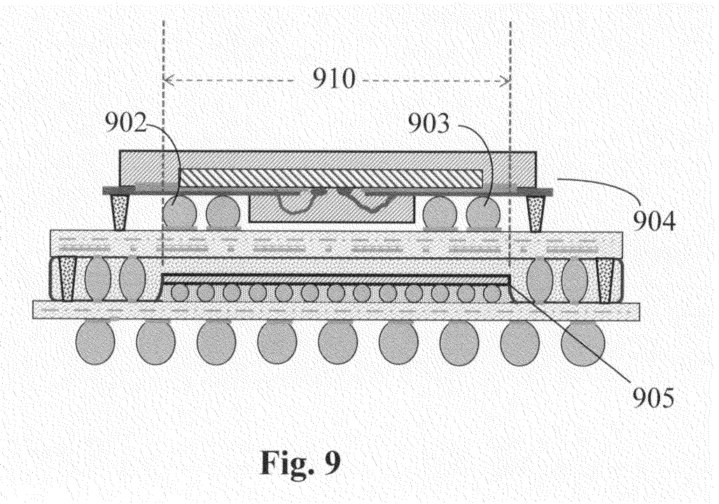

FIG. 9 indicates that stacking solder joints 902 and 903 can be placed directly over the die area 901 of bottom flip chip device using double layer of standoff structure. This is the unique capability provided by interposer in order to build the smallest footprint of P2P. Minimizing F2P size of 30 memory package 904 onto large processor chip 905, this kind of arrangement is the only way to achieve near chip size package (CSP) with P2P structure.

According to the drawings and the above descriptions, this application discloses an electronic package for containing and protecting stacked electronic packages therein. The electronic package further comprises an interposer including conductive traces interconnected between contact pads disposed on a top surface and a bottom surface of the interposer provided for mounting at least one of the stacked electronic packages on the top or bottom surface contacting the contact pads. In an embodiment, the interposer is a printed circuit board (PCB) interposer. In another embodiment, the interposer is a laminated printed circuit board (PCB) interposer including multiple laminated layers with the conductive traces disposed and interconnected between the multiple laminated layers. In another embodiment, at least one of the stacked electronic packages contains an integrated circuit (IC) chip. In another embodiment, the interposer is a printed circuit board (PCB) interposer with via connectors interconnecting the contact pads disposed on the top surface and the bottom surface of the PCT interposer. In another embodiment, the interposer is a laminated printed circuit board (PCB) interposer including multiple laminated layers with via connectors interconnecting the conductive traces disposed in the multiple laminated layers and the contact pads disposed on the top surface and the bottom surface of the laminated PCB interposer. In another embodiment, the interposer further includes standoffs disposed on [either a] (the) top surface [or a bottom surface](make the bottom surface another dependent claim) of the interposer. In another embodiment, the interposer further includes solder balls or conductive polymer bumps disposed on [either a] (the) top surface [or a bottom](make the bottom surface another dependent claim) surface of the interposer. In another embodiment, the interposer further includes passive electrical components disposed on either a top surface [or a bottom surface of the interposer and an underfill disposed below the interposer for filling and protecting a space between the interposer and the bottom package disposed below the interposer to improve thermal conduction of the stacked module. In another embodiment, at least one of the stacked electronic packages contains an integrated circuit (IC) chip formed in a semiconductor die for mounting from a bottom surface of the interposer; and the contact pads are formed as solder joints disposed on an area of the top surface directly above the semiconductor die to provide an optimal footprint of the electronic package. In another embodiment, the contact pads disposed on a top surface and a bottom surface are pre-designated contact pads designed and designated to match footprints of the electronic packaged for mounting onto the top and the bottom surfaces of the interposer.

Processing Flow of PCB Interposer Stacking

Step 1: Design the traces and contact pads correspond to the footprints 5 of stacking components.
Step 2: Aligned the top side of molded vias 111 and 117 in FIG. 1B with the contact pads on back side of interposer 102 in FIG. 1A. Properly designed standoffs can be used to ease this stacking alignment.
Step 3: Attach solder balls 122 FIG. 2 onto the backside contact pad 102 of 10 the interposer. Also verify that the footprints 116 of the top component align well with the top side interposer contact pads 101 and 107.
Step 4: Attach standoffs 120 in FIG. 3 onto the backside of interposer. One can choice different kinds of standoffs as described in the preferred embodiment. Note that the height of standoffs will determine the shape of truncated solder joints which will have significant impacts on the reliability of fatigue life.
Step 5: Reflow and connect solder joint 122 in FIG. 4 to the top side of molded via 128. Note that the mechanical standoffs 120 can be placed on top of the molded body 126 to provide a positive spacing. Even with subsequent multiple reflows, the solder joints will not collapse due to re-melting of solder joints or the weight of stacked structure. One can also choose to use elastomeric polymer balls 118 and 139 in FIG. 5 as standoffs with good compliant support and to provide flexibility. If bottom package uses flip chip interconnections as shown in 148 of FIG. 5, there will be a limitation on placing stacking solder joints. Since one can not make connects to the backside of flip chip. Thus, stacking joints have to be placed outside of flip chip area. But, with interposer and double standoffs stacking as shown in FIG. 9, this limitation will no longer applied.
Step 6. Attach and reflow all top side components; passives or active SMT package onto the top surface of interposer. At this step the P2P is completed and ready for functionally electrical testing.

Optional business approach can be considered to terminate at Step 5 of the process flow. Test and sell the interposer mounted part as component as illustrated in FIG. 7 This basic building block with customized footprints on the top surface interposer can be shipped to customers. Let the customers choose their favorite components to finish the P2P structure such as shown in FIG. 8 and FIG. 9

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. An electronic package for containing and protecting stacked electronic packages therein, further comprising:
an interposer including conductive traces interconnected between contact pads disposed on a top surface and a bottom surface of the interposer provided for mounting at least one of said stacked electronic packages on the top or bottom surface contacting the contact pads.

2. The electronic package of claim 1 wherein:
the interposer is a printed circuit board (PCB) interposer.

3. The electronic package of claim 1 wherein:
the interposer is a laminated printed circuit board (PCB) interposer including multiple laminated layers with said conductive traces disposed and interconnected between said multiple laminated layers.

4. The electronic package of claim 1 wherein:
at least one of the stacked electronic packages contains an integrated circuit (IC) chip.

5. The electronic package of claim 1 wherein:
the interposer is a printed circuit board (PCB) interposer with via connectors interconnecting said contact pads disposed on the top surface and the bottom surface of the PCT interposer.

6. The electronic package of claim 1 wherein:
the interposer is a laminated printed circuit board (PCB) interposer including multiple laminated layers with via connectors interconnecting said conductive traces disposed in said multiple laminated layers and said contact pads disposed on the top surface and the bottom surface of the laminated PCB interposer.

7. The electronic package of claim 1 wherein:
the interposer further includes standoffs disposed on [either a] (the) top surface [or a bottom surface](make the bottom surface another dependent claim) of the interposer.

8. The electronic package of claim 1 wherein:
the interposer further includes solder balls or conductive polymer bumps disposed on [either a] (the) top surface or a bottom surface of the interposer.

9. The electronic package of claim 1 wherein:
the interposer further includes passive electrical components disposed on either a top surface [or a bottom surface](make bottom surface another dependent claim) of the interposer.

10. The electronic package of claim 1 further comprising:
an underfill disposed below the interposer for filling and protecting a space between the interposer and the bottom package disposed below the interposer to improve thermal conduction of the stacked module.

11. The electronic package of claim 1 wherein:
at least one of the stacked electronic packages contains an integrated circuit (IC) chip formed in a semiconductor die for mounting from a bottom surface of the interposer; and
the contact pads are formed as solder joints disposed on an area of the top surface directly above the semiconductor die to provide an optimal footprint of the electronic package.

12. The electronic package of claim 1 wherein:
contact pads disposed on a top surface and a bottom surface are pre-designated contact pads designed and designated to match footprints of the electronic packaged for mounting onto the top and the bottom surfaces of the interposer.
